(19) United States
(12) Patent Application Publication
(10) Pub. No.: US 2025/0374472 A1
(43) Pub. Date: Dec. 4, 2025

(54) MULTIFUNCTIONAL CARRIER STRUCTURE

(71) Applicant: OXTI Pte Ltd, Singapore (SG)

(72) Inventor: Chih-Feng Ho, Singapore (SG)

(21) Appl. No.: 18/677,935

(22) Filed: May 30, 2024

(51) Int. Cl. H05K 7/16; H05K 5/02

(52) U.S. Cl. CPC H05K 7/16; H05K 5/0234

(57) ABSTRACT

A multifunctional carrier structure of an electronic device is provided, including: an electronic device; a support mechanism arranged, at intervals, at one side of the electronic device, where the support mechanism includes a main body and an extension arm, the extension arm being arranged on the main body; a rotation mechanism arranged between the electronic device and the support mechanism and including a first rotating portion and a second rotating portion, which are rotatably connected to each other, the first rotating portion being connected to the extension arm, the second rotating portion being connected to the electronic device; and a base connected to the man body of the support mechanism. In this way, the electronic device is provided with a function of rotation, and is also provided with a function of fixing on a desktop.

### BACKGROUND OF THE INVENTION

### (a) Technical Field of the Invention

The present invention relates to an electronic device, and more particularly to a multifunctional carrier structure.

### (b) Description of the Prior Art

Supportive stands for use with displays are known, such as Taiwan Utility Model M599368, which discloses a supportive stand including a base, an upright pillar, a hooking member, and a fastening member. The upright pillar is mounted on the base, and the hooking member is connected with the fastening member for combination and fixation to have the supportive stand firmly erected. Further, the upright pillar is provided with a carrying member for supporting a display.

The known supportive stands often use a fixing member (such as a pin, a bolt, and a spring) provided on an upright pillar to adjust a height-wise position of a display. Some implementation, however, must be assisted by additional tools for making adjustment. Further, most of the supportive stands can only be adjusted for the height-wise position of the display. In case that a user attempts to make rotation or adjustment to other angular positions for different conditions of uses, there will be situations where the supportive stands cannot be adjusted for such attempts. As such, there is still room for further improvement.

### SUMMARY OF THE INVENTION

To achieve above purpose, the present invention provides a multifunctional carrier structure, which comprises: an electronic device; a support mechanism, which is arranged, at intervals, at one side of the electronic device, the support mechanism comprising a main body and an extension arm, the extension arm being arranged on the main body; a rotation mechanism, which is arranged between the electronic device and the support mechanism, the rotation mechanism comprising a first rotating portion and a second rotating portion, the first rotating portion and the second rotating portion being rotatably connected to each other, the first rotating portion being connected to the extension arm, the second rotating portion being connected to the electronic device; and a base, which is connected to the main body of the support mechanism.

In the above structure, the rotation mechanism further comprises a first rotation axle, the first rotation axle being coupled between the first rotating portion and the second rotating portion, the first rotating portion and the second rotating portion being rotatably connected to each other by means of the first rotation axle.

In the above structure, the rotation mechanism comprises a connecting seat and a second rotation axle, the connecting seat and the second rotation axle being arranged between the second rotating portion and the electronic device, the second rotating portion and the electronic device being rotatably connected by means of the connecting seat and the second rotation axle.

In the above structure, the base comprises a clamping device or a board.

In the above structure, the base comprises a clamping device, the clamping device comprising a clamping body and at least one fastener, the fastener being arranged on the clamping body.

In the above structure, the electronic device comprises a tablet computer, a smart phone, an electronic reader, or a computer display.

In this way, the electronic device so mounted is provided with a function of rotation, and is also provided with a function of fixing to a desktop, to thereby suit the needs for various ways of use.

### BRIEF DESCRIPTION OF THE DRAWINGS

FIG. 1 is a schematic view showing the present invention.

FIG. 2 is a schematic view showing a portion of the present invention.

FIG. 3 is a schematic view illustrating operation of a rotation mechanism of the present invention.

FIG. 4 is a schematic view showing a fixing mechanism of the present invention.

FIG. 5 is a schematic view showing a base of the present invention that is made in the form of a board.

### DETAILED DESCRIPTION OF THE PREFERRED EMBODIMENTS

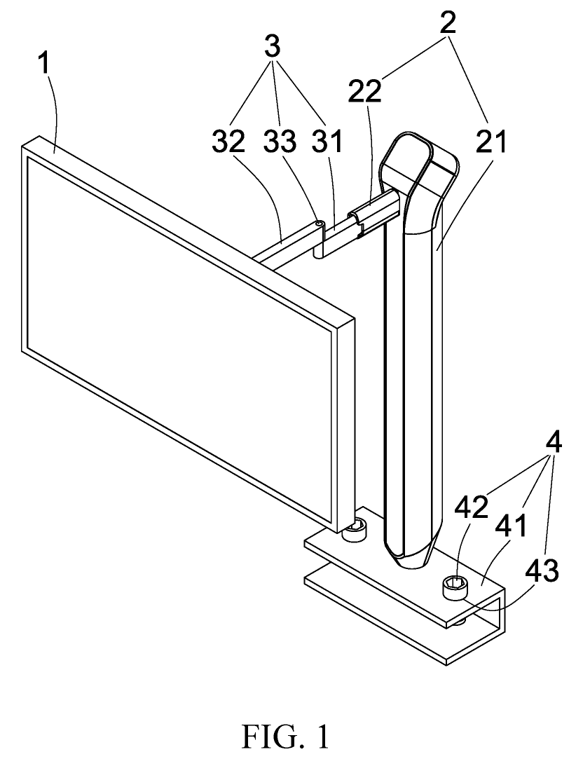

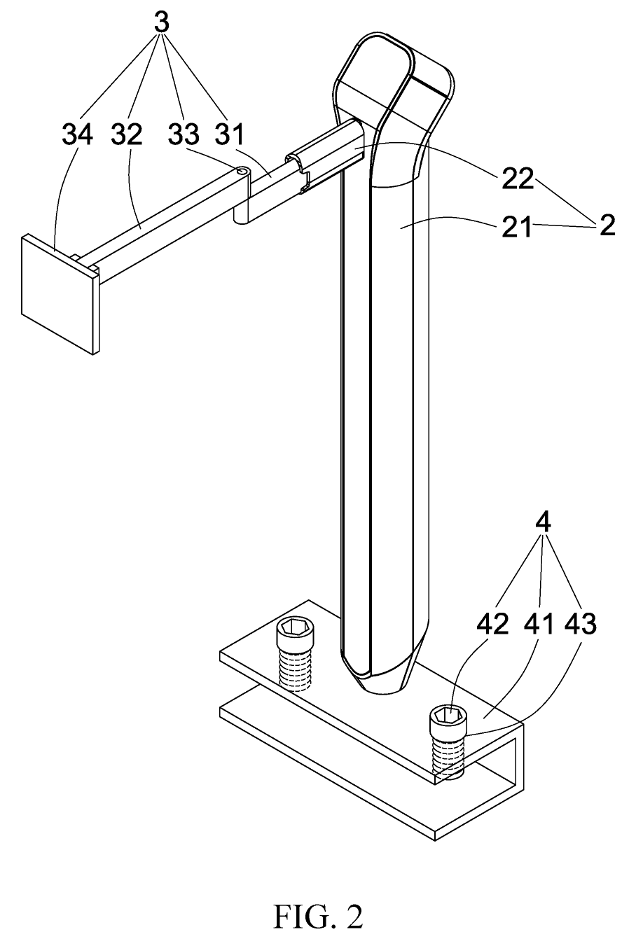

Referring to FIGS. 1 and 2, the present invention provides a multifunctional carrier structure, which comprises: an electronic device 1, a support mechanism 2, a rotation mechanism 3, and a base.

The electronic device 1 can be a tablet computer, a smart phone, an electronic reader, or a computer display, but is not limited thereto.

The support mechanism 2 is arranged, at intervals, at one side of the electronic device 1. The support mechanism 2 comprises a main body 21 and an extension arm 22. The extension arm 22 is arranged on the main body 21.

The rotation mechanism 3 is arranged between the electronic device 1 and the support mechanism 2. The rotation mechanism 3 comprises a first rotating portion 31 and a second rotating portion 32. The first rotating portion 31 and the second rotating portion 32 are rotatably connected to each other. The first rotating portion 31 is connected to the extension arm 22. The second rotating portion 32 is connected to the electronic device 1. The rotation mechanism 3 may further comprise a first rotation axle 33, and the first rotation axle 33 is coupled between the first rotating portion 31 and the second rotating portion 32. The first rotating portion 31 and the second rotating portion 32 are rotatably connected to each other by means of the first rotation axle 33.

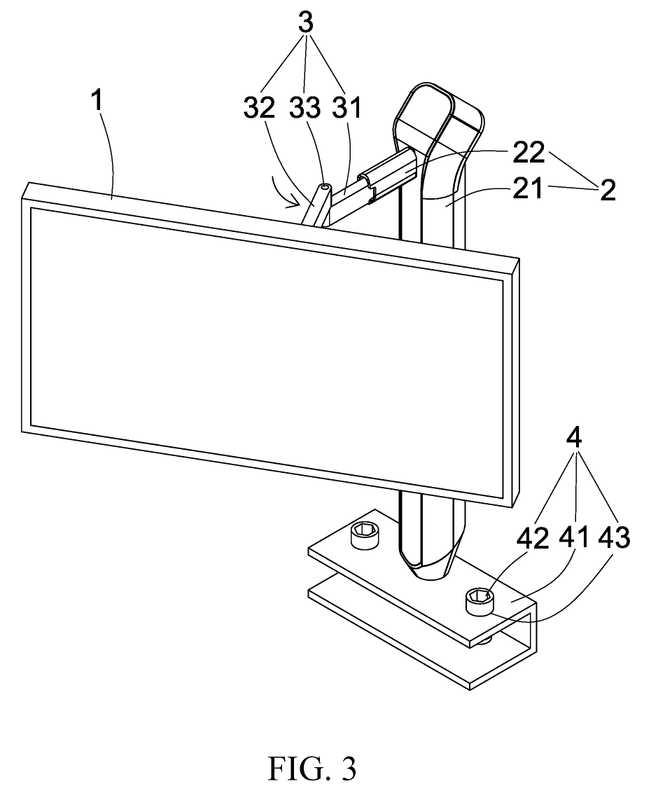

Referring to FIG. 3, when the user rotates the electronic device 1 leftwards and rightwards, the electronic device 1 causes the second rotating portion 32 to rotate leftwards and rightwards. Further, due to the first rotation axle 33 being coupled between the first rotating portion 31 and the second rotating portion 32, the second rotating portion 32 is rotatable relative to the first rotating portion 31 to fulfill the function of rotation.

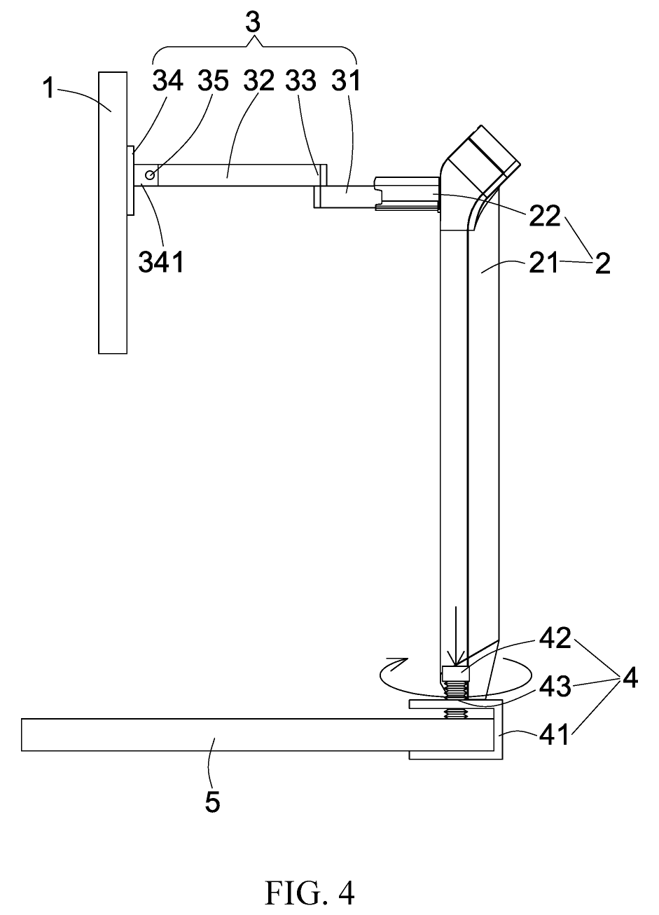

Referring to FIG. 4, the rotation mechanism 3 may further comprise a connecting seat 34 and a second rotation axle 35. The connecting seat 34 and the second rotation axle 35 are arranged between the second rotating portion 32 and the electronic device 1. A rotating connection is formed between the second rotating portion 32 and the electronic device 1 by means of the connecting seat 34 and the second rotation axle 35. Speaking in details, the connecting seat 34 is fixedly connected with the electronic device 1. For example, the connecting seat 34 may be formed with fastening holes, and the electronic device 1 is fastened to the fastening holes of the connecting seat 34. The connecting seat 34 is further provided with a sleeve 341 extending therefrom. The sleeve 341 is formed with an axle hole for receiving insertion of the second rotation axle 35. The second rotation axle 35 is arranged on the second rotating portion 32, and the second rotation axle 35 is inserted into the axle hole of the sleeve 341 to have the connecting seat 34 rotatable relative to the second rotating portion 32. As such, the user may rotate the electronic device 1 upwards and downwards to change a tilting angle of the electronic device 1 as desired.

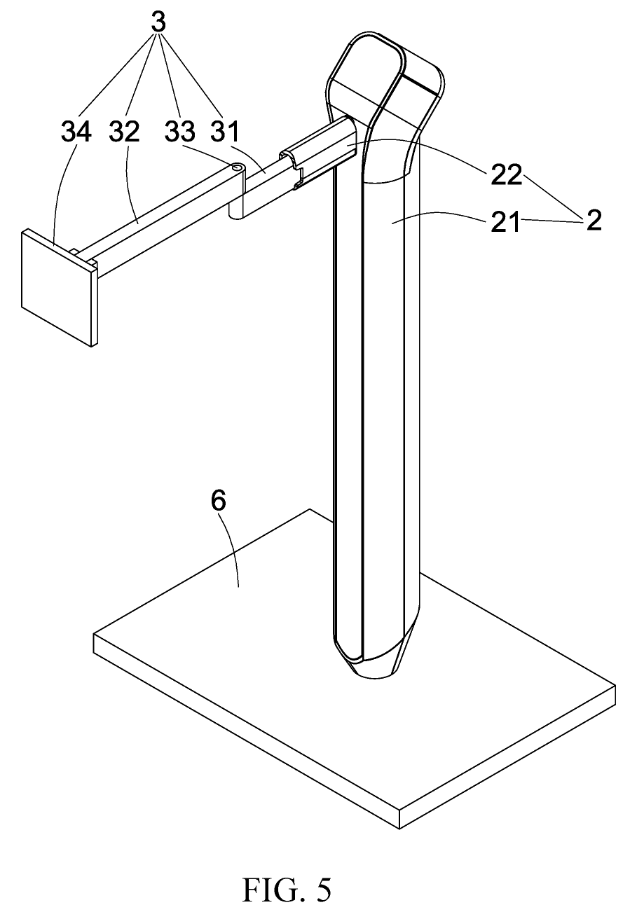

Referring to FIGS. 1 and 5, the base is connected to the main body 21 of the support mechanism 2. The base can be a clamping device 4 (shown in FIG. 1) or a board 6 (shown in FIG. 5). Speaking more specifically, in FIGS. 1 and 2, the clamping device 4 comprise a clamping body 41 and at least one fastener 42. The fastener 42 is arranged on the clamping body 41. The clamping body 41 is connected to the main body 21 of the support mechanism 2. Further, the clamping body 41 is made in the form of a frame. The clamping body 41 is formed with a threaded hole 43, and the fastener 42 comprises a screw. The screw penetrates into the threaded hole 43. Referring to FIG. 4, in this way, the user may use the clamping device 4 to clamp on a desktop 5, and the user may then penetrate the fastener 42 through the threaded hole 43 to have the fastener 42 abutting against the desktop 5, so as to make the clamping device 4 more firmly secured on the desktop 5 to fulfill the function of fixing to the desktop 5. In FIG. 5, the base comprises a board 6, which, although not fulfilling the function of fixing, is easy to move, and the user may make selection according to a practical need.

As such, the electronic device 1 mounted in this way is provided with a function of rotation, and is also provided with a function of fixing to a desktop 5, to thereby suit needs for various ways of use.

I claim:

1. A multifunctional carrier structure, comprising:
an electronic device;
a support mechanism, which is arranged, at intervals, at one side of the electronic device, the support mechanism comprising a main body and an extension arm, the extension arm being arranged on the main body;
a rotation mechanism, which is arranged between the electronic device and the support mechanism, the rotation mechanism comprising a first rotating portion and a second rotating portion, the first rotating portion and the second rotating portion being rotatably connected to each other, the first rotating portion being connected to the extension arm, the second rotating portion being connected to the electronic device; and
a base, which is connected to the main body of the support mechanism.

2. The multifunctional carrier structure according to claim 1, wherein the rotation mechanism further comprises a first rotation axle, the first rotation axle being coupled between the first rotating portion and the second rotating portion, the first rotating portion and the second rotating portion being rotatably connected to each other by means of the first rotation axle.

3. The multifunctional carrier structure according to claim 1, wherein the rotation mechanism comprises a connecting seat and a second rotation axle, the connecting seat and the second rotation axle being arranged between the second rotating portion and the electronic device, the second rotating portion and the electronic device being rotatably connected by means of the connecting seat and the second rotation axle.

4. The multifunctional carrier structure according to claim 1, wherein the base comprises a clamping device or a board.

5. The multifunctional carrier structure according to claim 1, wherein the base comprises a clamping device, the clamping device comprising a clamping body and at least one fastener, the fastener being arranged on the clamping body.

6. The multifunctional carrier structure according to claim 1, wherein the electronic device comprises a tablet computer, a smart phone, an electronic reader, or a computer display.
